(19) United States
(12) Patent Application Publication
(10) Pub. No.: US 2023/0108035 A1
(43) Pub. Date: Apr. 6, 2023

(54) PZN-BASED LARGE-SIZE TERNARY HIGH-PERFORMANCE SINGLE CRYSTAL, GROWING METHOD AND MOLTEN SALT FURNACE THEREOF

(71) Applicant: DONGGUAN UNIVERSITY OF TECHNOLOGY, Dongguan, Guangdong (CN)

(72) Inventor: Tao LI, Dongguan, Guangdong (CN)

(21) Appl. No.: 17/777,887

(22) PCT Filed: Dec. 13, 2021
(86) PCT No.: PCT/CN2021/137342

§ 371 Date: May 18, 2022

(30) Foreign Application Priority Data
Apr. 8, 2021 (CN) 202110378845.4

(51) Int. Cl. C30B 9/12; C30B 29/32; C30B 9/06; C01G 33/00; H10N 30/853; H10N 30/095

(52) U.S. Cl. CPC C30B 9/12; C30B 29/32; C30B 9/06; C01G 33/006; H01L 41/1876; H01L 41/41; C01P 2002/50; C01P 2006/40

(57) ABSTRACT

The present invention provides a PZN-based large-size ternary high-performance single crystal, a growing method and a molten salt furnace. The PZN-based large-size ternary high-performance single crystal is represented by formula (1-x-y)Pb(B′_{1/2}B″_{1/2})O₃-yPb(Zn_{1/3}Nb_{2/3})O₃-xPbTiO₃, wherein B′ is Mg, Fe, Sc, Ni, In, Yb, Lu and/or Ho, B″ is Nb, Ta and/or W, 0.4<x<0.6, 0.1<y<0.4, 0.1<1-x-y<0.4. The present invention adjusts the convective change of the melt through the rotation of the top seed and the bottom crucible, overcoming the problems of serious crystal inclusions and poor crystal quality during the growth process, and can adapt the change of the crystal diameter to the thermal inertia of the heat preservation system, thus effectively reducing crystal inclusions and improving the yield of the crystal.

### TECHNICAL FIELD

The present invention relates to a crystal material and growth method and growth equipment thereof, in particular to a PZN-based large-size ternary high-performance single crystal, a growth method and a molten salt furnace thereof.

### BACKGROUND

PZN-based (Pb (Zn_{1/3}Nb_{2/3}) O₃) relaxor ferroelectric single crystal has attracted extensive attention because of its ultra-high piezoelectric coefficient and electromechanical coupling coefficient. At present, PZN-based binary high-performance single crystal PZN-PT has been prepared. At room temperature, PZN has a trigonal structure with a Curie temperature of 140° C., and PT has a tetragonal structure with a Curie temperature of 490° C. Near the quasi-homogeneous phase boundary, PZN-PT exhibits excellent piezoelectric properties with piezoelectric coefficient d₃₃>2000 pC/N, electromechanical coupling coefficient k₃₃>90%, electric field induced strain up to 1.7%, dielectric constant around 4000, and dielectric loss below 1%. Due to the inherent defects of PZN-PT ferroelectric single crystals, the modification of PZN-PT ferroelectric single crystals has become the focus of attention.

In addition, the main technical bottleneck for the commercial application of relaxor ferroelectric single crystals lies in the preparation of single crystals. Since relaxor ferroelectric single crystals are formed in a multi-component system, such as PbO—MgO(ZnO)—Nb₂O₅—TiO₂ system, complex crystallization routes will occur during the cooling of the melt, making crystal growth difficult.

At present, the methods for growing relaxor ferroelectric single crystals include high-temperature solution growth method, vertical Bridgman growth method and top-seeded solution growth (TSSG) method.

The high-temperature solution growth method is highly applicable, in which the flux can lower the growth temperature, bringing unique advantages. However, for relaxor ferroelectric single crystals, the nucleation is difficult to control, the size of the obtained crystals is relatively small, and it is easy to produce flux inclusions, which affects the crystal quality.

The advantages of the vertical Bridgman growth method include large crystal size and short crystal growth cycle, but the high growth temperature causes the lead-containing raw material to corrode the crucible seriously and the preparation cost is high. In addition, due to the non-uniform melting of components and the influence of component segregation, the bottom and top components of the grown crystals are not uniform, and the performance deviation is large, which affects the uniformity and consistency of crystal quality.

The TSSG method was actually developed on the basis of the high temperature solution growth method and overcomes some shortcomings of the latter. For example, the single nucleus growth is beneficial to obtain single crystals of high quality and large size, and the composition uniformity is improved. However, the TSSG method can lead to slow crystal growth and inclusion defects due to the low solubility of flux.

Moreover, for the preparation of relaxor ferroelectric single crystals, the existing equipment generally has defects such as uneven temperature control, resulting in that the performance of the final relaxor ferroelectric single crystals cannot be effectively guaranteed.

In view of the above-mentioned defects of the relaxor ferroelectric single crystals and growth thereof, based on years of rich experience and professional knowledge in such materials, combined with theoretical analysis, the inventor of the present invention conducts research and innovation, in order to develop a PZN-based large-size ternary high-performance single crystal, a growth method and a molten salt furnace, which can improve the stability of the crystal and make the preparation process easier to implement.

### SUMMARY

The principle of the present invention is to mix crystal raw materials and a flux, load the mixture into a crucible and then place the crucible in a molten salt furnace for crystal growth, raise the temperature to above the melting temperature and keep it for a sufficient time to make the melt fully uniform, and then cool down to below the saturation growth temperature to start crystal growth. As the temperature is lowered, the temperature gradient during growth is controlled so that the seed is not melted off at the saturation growth temperature and crystals begin to grow on the seed. Adjusting the convective change of the melt by rotating the top seed and the bottom crucible can make the change of crystal diameter adapt to the thermal inertia of the heat preservation system, thereby reducing crystal inclusions. After the crystal growth is complete, the crystal is lifted out of the liquid surface and then cooled and annealed.

A first object of the present invention is to provide a PZN-based large-size ternary high-performance single crystal with improved crystal stability.

This technical object of the present invention is achieved by the following technical solution.

A PZN-based large-size ternary high-performance single crystal represented by formula (1-x-y)Pb(B′_{1/2}B″_{1/2})O₃-yPb(Zn_{1/3}Nb_{2/3})O₃-xPbTiO₃, wherein B′ is Mg, Fe, Sc, Ni, In, Yb, Lu and/or Ho, B″ is Nb, Ta and/or W, 0.4<x<0.6, 0.1<y<0.4, 0.1<1-x-y<0.4.

Another object of the present invention is to provide a method for growing a PZN-based large-size ternary high-performance single crystal.

This technical object of the present invention is achieved by the following technical solution.

A method for growing a PZN-based large-size ternary high-performance single crystal, comprising the steps of:

mixing of raw materials (S1), including weighing the raw materials according to the stoichiometric ratio of the relaxor ferroelectric single crystal, adding a flux to the raw materials, mixing the raw materials and the flux evenly and grinding the same, and loading the resultant into a crucible for subsequent use, wherein the stoichiometric ratio of relaxor ferroelectric single crystal refers to the chemical formula (1-x-y)Pb(B′_{1/2}B″_{1/2})O₃-yPb(Zn_{1/3}Nb_{2/3})O₃-xPbTiO₃, wherein B′ is Mg, Fe, Sc, Ni, In, Yb, Lu and/or Ho, B″ is Nb, Ta and/or W, 0.4<x<0.6, 0.1<y<0.4, 0.1<1-x-y<0.4;

positioning of seed (S2), including transferring the crucible containing the raw materials and flux to a molten salt furnace, fixing a seed on a seed rod, adjusting the position of the seed rod in the molten salt furnace so that the molten salt furnace, crucible and seed are centered on a line;

crystal growth (S3), including heating the materials in the crucible to a molten state and maintaining the same at a constant temperature to obtain a melt, then moving the seed rod to adjust the seed to meet the liquid level of the melt, followed by cooling to a temperature below the saturation point for crystal growth, wherein during the growth process, the convective changes of the melt are adjusted by rotating the seed rod and crucible; and

cooling and annealing (S4), including lifting the crystal from the melt when the crystal grows to a preset size, and cooling and annealing the crystal to obtain the target product.

Preferably, the added flux is a composite flux, comprising a mixture of PbO and B₂O₃ in a mass ratio of 3-10:0.1-3, or a mixture of PbO and PbF₂ in a mass ratio of 2-10:0.3-2.8.

Preferably, the added flux is a composite flux, comprising a mixture of PbO and B₂O₃ in a mass ratio of 4-7:0.7-1, or a mixture of PbO and PbF2 in a mass ratio of 4-7.2:0.7-1.2.

By using the compound of lead oxide and boric acid, on the one hand, the potential safety hazards such as high-temperature explosion between the flux and the added materials during high-temperature heating can be avoided, on the other hand, the compounded flux helps to accelerate the melting of raw materials and shortens the heating process, saving energy.

Preferably, the seed in the step S2 has the same composition as the PZN-based large-size ternary high-performance single crystal prepared by cooling and annealing in step S4, and the growth orientation of the seed is [111] or [001].

Preferably, the crucible used is a platinum crucible to avoid corrosion.

Preferably, the size of the PZN-based large-size ternary high-performance single crystal obtained in step S4 is 30-50 mm×30-50 mm×10-20 mm.

Preferably, in the step S3, the relative rotation speed of the seed rod and the crucible is kept at ±1-54r/min, so that the melt is always in a relatively stable convective change, thereby avoiding the interference of heat change in the crystal growth process and minimizing the crystal inclusions.

Preferably, in the step S3, the cooling rate is less than 10° C./day, the main purpose of which is to match the relative rotational speed of the seed rod and crucible, so that the crystal adapts to the thermal inertia of the melt during the growth process, avoiding defects such as crystal inclusions.

Preferably, in the step S3, the cooling rate is 2-8° C./day.

Preferably, in the step S3, the melting temperature is 900-1150° C., preferably 1000-1100° C.; the constant temperature time is 1-6 days, preferably 2-3 days.

Preferably, in the step S3, the crystal growth temperature is 850-1050° C., preferably 900-1000° C.

Preferably, in the step S4, the annealing cooling rate is less than 50° C./h and the temperature after annealing is 10-30° C. The strict control of the annealing cooling rate is also to make the final crystal growth size meet the requirements, reduce the defects introduced during the annealing process as much as possible, as well as to ensure the stability of the final crystal.

Preferably, in the step S4, the annealing cooling rate is 15-30° C./h, and the temperature after annealing is 25-30° C.

A yet another object of the present invention is to provide a molten salt furnace for a PZN-based large-size ternary high-performance single crystal.

This technical object of the present invention is achieved by the following technical solution.

A molten salt furnace for use in the method for growing a PZN-based large-size ternary high-performance single crystal described above, comprising a furnace body provided with a cylindrical inner cavity, wherein a rotary motor is provided at the bottom of the furnace body and a rotary crucible base driven by the rotary motor is provided at the bottom of the cylindrical inner cavity of the furnace body, wherein a seed rod position adjustment device is provided on the outer side of the furnace body, and wherein the bottom of the seed rod position adjustment device fixes a seed rod inserted into the cylindrical inner cavity of the furnace body and drives the seed rod to rotate.

Preferably, the crucible base is supported at the bottom of the cylindrical inner cavity through a support rod, wherein a lower end of the support rod extends to the outside of the furnace body and is fixedly provided with a first bevel gear, and wherein an end of output shaft of the rotary motor is connected to a second bevel gear meshed with the first bevel gear.

Preferably, the crucible base comprise a mounting seat fixedly connected to the support rod, and a cover fitted with the top of the mounting seat and supporting the crucible;

wherein at least three guide blocks and buffer springs equal to the number of the guide blocks are evenly distributed inside the mounting seat along the circumferential direction, the buffer springs passing through horizontal through holes formed in the guide blocks, the guide blocks are further provided with an installation groove in which a limit block and an elastic pressing strip are arranged and a pressing plate, the installation groove is configured to guide the limit block in a vertical direction, wherein the elastic pressing strip is fitted with the upper surface of the guide block, which upper surface is provided with a guide groove for the two ends of the elastic pressing strip to slide, wherein the pressing plate is fitted with the top of the guide blocks to seal the top of the guide groove, and the elastic pressing strip provides a vertical downward pressing force for the limit block through elastic deformation;

wherein a protrusion and two abutting surfaces located on either side of the protrusion in the length direction of the buffer springs are provided on the bottom of the limit block, wherein the abutting surfaces are fitted with the buffer springs, the protrusion is inserted between two adjacent turns of the buffer springs when the buffer springs are stationary, and the cross section of the protrusion in the radial direction of the buffer springs is an isosceles trapezoid; and

wherein an inner side of the cover is provided with baffle plates equal to the number of the buffer springs, wherein the baffle plates are arranged between two adjacent buffer springs to press the buffer springs on one side during the relative rotation of the mounting base and the cover.

Preferably, seed rod position adjustment device includes a base on which a lifting fixing plate is vertically arranged, wherein a first lifting rod and a second lifting rod are provided in parallel on either side of the lifting fixing plate, a first driving gear opposite to the first lifting rod and a second driving gear opposite to the second lifting rod are provided on the top of the lifting fixing plate, wherein the first lifting rod is provided with a counterweight slider that slides up and down and the second lifting rod is provided with a lifting slider that slides up and down, the counterweight slider and the lifting slider being controlled by a lifting rack meshed with the first driving gear and the second driving gear of a lifting driving component, and wherein the lifting slider is connected to an adjustment arm, the bottom of the adjustment arm fixing the seed rod.

Preferably, the adjustment arm includes a left and right adjustment joint having one end connected to the lifting slider and the other end connected to one end of a front and rear adjustment joint, the bottom of the front and rear adjustment joint fixing the seed rod.

Preferably, the other end of the front and rear adjustment joint is provided with a connecting seat connected to a motor fixing bracket on which a servo motor is arranged, an output shaft of the servo motor being connected to the seed rod through a coupling.

Preferably, the left and right adjustment joint comprises a left and right adjustment seat and a left and right rack arranged on the front and rear sides of the inner wall of the left and right adjustment seat, wherein the left and right adjustment seat comprises a left and right adjustment gear meshed with the left and right rack, the left and right adjustment gear is connected to a left and right adjustment bolt that is rotated to drive the left and right adjustment gear to rotate, the left and right adjustment gear is connected to one end of a left and right adjustment shaft through a connecting head, and the other end of the left and right adjustment shaft is connected to the front and rear adjustment joint through a connecting body.

Preferably, the front and rear adjustment joint comprises a front and rear adjustment seat, a front and rear adjustment screw, a front and rear adjustment slider, a front and rear adjustment bolt, and a front and rear adjustment screw lock nut, wherein the front and rear adjustment seat is connected to the connecting body of the left and right adjustment joint, the front and rear adjustment screw lock nut is connected on the front and rear adjustment seat, and the front and rear adjustment slider is threaded to the front and rear adjustment screw rod.

Preferably, the lifting driving component further comprises a first driven gear, a second driven gear and a gearbox, wherein the first driving gear and the second driving gear are connected to the gearbox through a driving shaft, the first driven gear and the second driven gear are connected to the gearbox through a driven shaft, the interior of the gearbox is further provided with a first transmission gear keyed to the driving shaft and a second transmission gear keyed to the driven shaft, and the driving shaft is connected to the gearbox at one end thereof and the output shaft of a lifting drive motor at the other end thereof.

Preferably, a bearing is provided at the connection between the driving shaft and the gearbox and between the driven shaft and the gearbox, wherein the bearing is fixed on the gearbox through a long bushing arranged on the side of the first driving gear and the first driven gear and a short bushing arranged on the side of the second driving gear and the second driven gear.

Preferably, the bottom of the furnace body is provided with a thermal insulation bottom plate, the casing of the furnace body is provided with a thermal insulation jacket, and the upper part of the furnace body is provided with a heat preservation cover and a thermal insulation cover arranged between the mouth of the cylindrical inner cavity of the furnace body and the heat preservation cover.

To sum up, the present invention has the following beneficial effects.

1. The present invention offers a higher yield. The present invention adjusts the convective change of the melt through the rotation of the top seed and the bottom crucible, overcoming the problems of serious crystal inclusions and poor crystal quality during the growth process, and can adapt the change of the crystal diameter to the thermal inertia of the heat preservation system, thus effectively reducing crystal inclusions and improving the yield of the crystal.

2. The crystals have good uniformity. The crystals prepared by the method according to the present invention, with the PZN ternary system formed, have the advantages of good quality, high uniformity and good crystal stability.

3. The growth method is easy to implement. The overall idea of the present invention concerns the TSSG method. The overall process is easy to control and the growth cycle is short, which can significantly save the production costs.

4. With the proposed molten salt furnace the present invention achieves melt convection through the crucible base and the top seed rod rotating in the opposite directions, so that the change of crystal diameter can adapt to the thermal inertia of the heat preservation system in the furnace, effectively reducing the crystal inclusions, promoting the growth of large-size crystals and improving the yield of crystals. It also effectively simplifies the structure of the furnace body and realizes efficient crystal production.

### DESCRIPTION OF THE DRAWINGS

FIG. 1 is a structural diagram of a molten salt furnace for a PZN-based large-size ternary high-performance single crystal according to the present invention;

FIG. 2 is a left side view of FIG. 1;

FIG. 3 is a top view of FIG. 1;

FIG. 4 is a structural diagram of an adjustment arm in the molten salt furnace for a PZN-based large-size ternary high-performance single crystal according to the present invention;

FIG. 5 is a schematic cross-sectional view of the adjustment arm in the molten salt furnace for a PZN-based large-size ternary high-performance single crystal according to the present invention;

FIG. 6 illustrates a temperature control system of the molten salt furnace for a PZN-based large-size ternary high-performance single crystal according to the present invention;

FIG. 7 is a schematic diagram of the connection between the crucible base and the support rod;

FIG. 8 is a structural diagram of the mounting seat and the internal structure;

FIG. 9 is a partial enlarged view at the position of the guide block;

FIG. 10 is an installation diagram of elastic pressing strip;

FIG. 11 is a structural diagram of the limit block;

FIG. 12 is a structural diagram of the cover;

FIG. 13 is a partial sectional view at the position of the guide block;

FIG. 14 is a schematic diagram of one side of the buffer spring in FIG. 13 in a compressed state; and

FIG. 15 is a schematic diagram of the working position of the baffle plate.

List of reference signs: 1. Furnace body; 101. Casing; 102. Thermal insulation jacket; 103. High-temperature furnace wire; 104. Wire winding tube; 105. Thermal insulation cover; 106. Heat preservation cover; 107. Thermal insulation bottom plate; 108. Crucible base; 1081. Mounting seat; 1082. Cover; 10821. Baffle plate; 1083. Guide block; 1084. Buffer spring; 1085. Installation groove; 1086. Pressing plate; 1087. Limit block; 10871. Protrusion; 10872. Abutting surface; 1088. Elastic pressing strip; 1089. Annular groove; 109. Crucible; 110. Support rod; 111. Thermocouple; 112. Furnace body balance adjustment device; 113. Sealing block; 114. First bevel gear; 115. Locking block; 116. Motor support; 117. Bevel gear II; 118. Rotary motor; 2. Seed rod module; 201. Seed collet; 202. Seed rod; 203. Guide bearing; 204. Coupling; 205. Connecting seat; 206. Motor fixing bracket; 207. Servo motor; 3. Seed rod position adjustment device; 31. Adjustment arm; 3101. Left and right adjustment joint; 3102, Front and rear adjustment joint; 3104. Left and right adjustment seat; 3105. Left and right rack; 3106. Left and right adjustment gear; 3103. Left and right adjustment bolt; 3107. Connecting head; 3108. Left and right adjustment shaft; 3109. Connecting body; 3110. Front and rear adjustment seat; 3114. Front and rear adjustment screw rod; 3112. Front and rear adjustment slider; 3111. Front and rear adjustment bolt; 3113. Front and rear adjustment screw rod lock nut; 3114. Front and rear adjustment screw rod; 32. Lifting adjustment seat; 3201. First lifting rod; 3202. Second lifting rod; 3203. Base; 3204. lifting fixing plate; 3205. Lifting rod fixing seat; 3206. First driving gear; 3207. Second driving gear; 3208. First driven gear; 3209. Second driven gear; 3210. Gearbox; 3211. First transmission gear; 3212. Second transmission gear; 3213. Transmission shaft; 3214. Driving shaft; 3215. Driven shaft; 3216. Lifting drive motor; 3217. Long shaft sleeve; 3218. Bearing; 3219. Short shaft sleeve; 33. Lifting rack; 34. Counterweight slider; 35. Lifting slider.

### DETAILED DESCRIPTION

To further illustrate the technical means adopted by the present invention to achieve the objects of the present invention and effects thereof, the specific embodiments, features and effects of the PZN-based large-size ternary high-performance single crystal, the growth method and the molten salt furnace proposed by the present invention are described in detail as follows.

### Example 1

A method of preparing a PZN-based large-size ternary high-performance single crystal represented by formula 0.3Pb(In_{1/2}Nb_{1/2})O₃-0.2Pb(Zn_{1/3}Nb_{2/3})O₃-0.5PbTiO₃ through TSSG process using PbO and B₂O₃ as flux in a molten salt furnace comprising a rotatable seed rod and a rotatable crucible, the method comprises the following steps:

S1 of weighing raw materials PbO, In₂O₃, ZnO, Nb₂O₅, TiO₂ and B₂O₃ according to the stoichiometric ratio of the formula of the crystal, mixing the raw materials with the flux, grinding the mixture and loading the resultant into the crucible;

S2 of fixing a seed on the seed rod, and adjusting the seed rod left and right such that the molten salt furnace, the crucible and the seed are centered on a line;

S3 of heating the raw materials to 1050° C. to melt, keeping the temperature constant for 3 days to obtain a melt, adjusting the seed to meet the liquid level of the melt, finding the saturation temperature and then cooling to below the supersaturation temperature for crystal growth, wherein the cooling rate is 3° C./day, and wherein during the growth process, the convective change of the melt is adjusted by rotating the seed rod and crucible;

S4 of lifting the crystal from the melt when the temperature drops to 950° C. and the crystal grows to a preset size, and cooling and annealing the crystal to obtain the PZN-based large-size single crystal, wherein the annealing cooling rate is 20° C./h, and the temperature after annealing is 25° C.

The growth orientation of the PIN-PZN-PT ternary high-performance single crystal prepared in Example 1 is (111), and the size is 40 mm×40 mm×15 mm.

### Example 2

Example 2 is the same with Example 1 except that the single crystal is represented by formula 0.35Pb(In_{1/2}Nb_{1/2})O₃-0.2Pb(Zn_{1/3}Nb_{2/3})O₃-0.45PbTiO₃, meaning that the weighing ratio of the raw materials is changed accordingly.

The growth orientation of the PIN-PZN-PT ternary high-performance single crystal prepared is (001), and the size is 30 mm×40 mm×15 mm.

### Example 3

Example 3 is the same with Example 1 except that the single crystal is represented by formula 0.25Pb(In_{1/2}Nb_{1/2})O₃-0.2Pb(Zn_{1/3}Nb_{2/3})O₃-0.55PbTiO₃, meaning that the weighing ratio of the raw materials is changed accordingly.

The growth orientation of the PIN-PZN-PT ternary high-performance single crystal prepared is (001), and the size is 50 mm×40 mm×20 mm.

### Example 4

Example 4 is the same with Example 1 except that the single crystal is represented by formula 0.15Pb(In_{1/2}Nb_{1/2})O₃-0.35Pb(Zn_{1/3}Nb_{2/3})O₃-0.5PbTiO₃, meaning that the weighing ratio of the raw materials is changed accordingly.

The growth orientation of the PIN-PZN-PT ternary high-performance single crystal prepared is (111), and the size is 40 mm×30 mm×20 mm.

### Example 5

Example 5 is the same with Example 1 except that the single crystal is represented by formula 0.35Pb(In_{1/2}Nb_{1/2})O₃-0.15Pb(Zn_{1/3}Nb_{2/3})O₃-0.5PbTiO₃, meaning that the weighing ratio of the raw materials is changed accordingly.

The growth orientation of the PIN-PZN-PT ternary high-performance single crystal prepared is (111), and the size is 40 mm×50 mm×10 mm.

### Example 6

Example 6 is the same as Example 1 except that the flux is a composite of PbO and BaTiO₃ in a mass ratio of 4:0.9.

The growth orientation of the PIN-PZN-PT ternary high-performance single crystal prepared is (111), and the size is 40 mm×40 mm×15 mm.

### Example 7

Example 7 is the same as Example 1 except that the flux is a composite of PbO and PbF₂ in a mass ratio of 5:1.

The growth orientation of the PIN-PZN-PT ternary high-performance single crystal prepared is (111), and the size is 40 mm×40 mm×15 mm.

### Example 8

Example 8 is the same as Example 1 except that the flux is a composite of PbO, B₂O₃ and BaTiO₃ in a mass ratio of 4:0.7:1.

The growth orientation of the PIN-PZN-PT ternary high-performance single crystal prepared is (001), and the size is 30 mm×50 mm×15 mm.

The yield and piezoelectric constant d₃₃ of the PIN-PZN-PT ternary high-performance single crystal prepared in Examples 1-8 are indicated in Table 1. It can be seen that the yields of Examples 1-8 are all above 95% and the d₃₃ is between 2650-2728 pC/N. In contrast, the d₃₃ of the PZN-PT binary single crystal is around 2100 pC/N. The d₃₃ of the PIN-PZN-PT ternary single crystal prepared in the prior art is between 2500-2600 pC/N, and the yield is lower than 95% of the present invention, indicating that the PIN-PZN-PT ternary high-performance single crystal prepared by the present invention has better piezoelectric performance and higher quality.

TABLE 1
Yield and Piezoelectric Constant of Examples 1-8

| Example | Yield (%) | d₃₃ (pC/N) |
|---|---|---|
| 1 | 96.5 | 2720 |
| 2 | 96.1 | 2680 |
| 3 | 96.2 | 2715 |
| 4 | 95.8 | 2728 |
| 5 | 96.1 | 2685 |
| 6 | 95.5 | 2676 |
| 7 | 95.3 | 2655 |
| 8 | 95.6 | 2670 |

### Examples 9-16

Examples 9-16 are the same as Examples 1-8 except that the single crystal is represented by formula 1-x-yPb(Lu_{1/2}Nb_{1/2})O₃-yPb(Zn_{1/3}Nb_{2/3})O₃-xPbTiO₃ and that in step S1 the PbO, MgO, ZnO, Nb₂O₅, TiO₂ and B₂O₃ are weighed according to the stoichiometric ratio of the foresaid formula.

The growth orientation and size of the PLuN-PZN-PT ternary high-performance single crystal prepared in Examples 9-16 are the same as those in Examples 1-8, respectively.

The yield and piezoelectric constant d₃₃ of the PLuN-PZN-PT ternary high-performance single crystal prepared in Examples 9-16 are indicated in Table 2. It can be seen that the yield has little change compared with Examples 1-8, and d₃₃ is between 2560-2620 pC/N, which is lower than that of Examples 1-8, but still higher than the piezoelectric constant of the PLuN-PZN-PT single crystal prepared in the prior art.

TABLE 2
Yield and Piezoelectric Constant of Examples 9-16

| Example | Yield (%) | d₃₃ (pC/N) |
|---|---|---|
| 9 | 96.3 | 2618 |
| 10 | 96.1 | 2576 |
| 11 | 96.0 | 2610 |
| 12 | 95.6 | 2620 |
| 13 | 95.9 | 2580 |
| 14 | 95.5 | 2570 |
| 15 | 95.2 | 2560 |
| 16 | 95.4 | 2565 |

### Example 17

Example 17 is the same as Example 1 except that the single crystal is represented by formula 0.2Pb(In_{1/2}Ta_{1/2})O₃-0.3Pb(Zn_{1/3}Nb_{2/3})O₃-0.5PbTiO₃ and that in step S1 the PbO, In₂O₃, Ta₂O₅, ZnO, Nb₂O₅, TiO₂ and B₂O₃ are weighed according to the stoichiometric ratio of the foresaid formula.

The growth orientation and size of the PLuN-PZN-PT ternary high-performance single crystal prepared in Example 17 are the same as those in Example 1, respectively. The yield of the single crystal is 95.6%, and the piezoelectric constant d₃₃ is 2380 pC/N.

### Example 18

Example 18 is the same as Example 1 except that the single crystal is represented by formula 0.3Pb(Sc1/2Nb1/2)O3-0.2Pb(Zn1/3Nb2/3)O3-0.5PbTiO3 and that in step S1 the PbO, Sc2O3, ZnO, Nb2O5, TiO2 and B2O3 are weighed according to the stoichiometric ratio of the foresaid formula.

The growth orientation and size of the PScN-PZN-PT ternary high-performance single crystal prepared in Example 17 are the same as those in Example 1, respectively. The yield of the single crystal is 95.8%, and the piezoelectric constant d₃₃ is 1960 pC/N.

### Examples 19-32

Examples 19-32 are the same as Example 1 except for the PIN-PZN-PT preparation conditions as indicated in Table 3.

TABLE 3
Preparation Conditions of Examples 19-32

| | | Constant | | Growth | | Annealing |
|---|---|---|---|---|---|---|
| | Constant | temperature | Cooling | endpoint | Annealing | endpoint |
| | temperature | time | rate | temperature | rate | temperature |
| Example | (° C.) | (day) | (° C./day) | (° C.) | (° C./hour) | (° C.) |
| 19 | 950 | 6 | 2 | 900 | 15 | 20 |
| 20 | 1020 | 5 | 3 | 900 | 15 | 25 |
| 21 | 1080 | 4 | 4 | 950 | 25 | 30 |
| 22 | 1150 | 3 | 5 | 950 | 30 | 25 |
| 23 | 1050 | 1 | 3 | 950 | 20 | 25 |
| 24 | 1050 | 6 | 3 | 950 | 20 | 25 |
| 25 | 1050 | 3 | 1 | 950 | 20 | 25 |
| 26 | 1050 | 3 | 8 | 950 | 20 | 25 |
| 27 | 1050 | 3 | 10 | 950 | 20 | 25 |
| 28 | 1050 | 3 | 3 | 900 | 20 | 25 |
| 29 | 1050 | 3 | 3 | 1000 | 20 | 25 |
| 30 | 1050 | 3 | 3 | 950 | 10 | 25 |
| 31 | 1050 | 3 | 3 | 950 | 50 | 25 |
| 32 | 1050 | 3 | 3 | 950 | 20 | 10 |

The growth orientation and size of the PIN-PZN-PT ternary high-performance single crystal prepared in Examples 19-32 are the same as those in Example 1, respectively.

The yield and piezoelectric constant d₃₃ of the PIN-PZN-PT ternary high-performance single crystal prepared in Examples 19-32 are indicated in Table 4. It can be seen from Examples 19-22 and Example 1 that with the increase of constant temperature, the yield and d₃₃ first increase and then decrease, and the yield and d₃₃ are relatively higher in the range of 1020-1080° C. It can be seen from Examples 23-27 and Example 1 that prolonging the constant temperature time and reducing the cooling rate are helpful to improve the yield and d₃₃; the constant temperature time is preferably 2-3 days and the cooling rate is preferably 2-5° C./day considering the shortening of the growth cycle. It can be seen from Examples 28-32 and Example 1 that too high or too low growth endpoint temperature is detrimental to the performance of the single crystal. As the cooling rate decreases, the yield of the single crystal and d₃₃ first increase and then decrease. When the annealing endpoint temperature decreases, the single crystal yield and d₃₃ decrease. Therefore, the growth endpoint temperature is preferably 950-1050° C., the annealing cooling rate is preferably 15-30° C./h, and the annealing endpoint temperature is preferably 20-30° C.

TABLE 4
Yield and Piezoelectric Constant of Examples 19-32

| Example | Yield (%) | d₃₃ (pC/N) |
|---|---|---|
| 19 | 93.2 | 2656 |
| 20 | 94.5 | 2695 |
| 21 | 95.2 | 2688 |
| 22 | 94.5 | 2705 |
| 23 | 93.5 | 2672 |
| 24 | 96.4 | 2718 |
| 25 | 96.0 | 2715 |
| 26 | 95.2 | 2686 |
| 27 | 94.8 | 2672 |
| 28 | 94.5 | 2674 |
| 29 | 93.5 | 2655 |
| 30 | 95.6 | 2695 |
| 31 | 94.2 | 2665 |
| 32 | 95.5 | 2685 |

The structure of the molten salt furnace for preparing crystal according to the present invention will be described.

The present invention discloses specific structure of a molten salt furnace for preparing a PZN-based large-size ternary high-performance single crystal, comprising a furnace body provided with a cylindrical inner cavity, wherein a rotary motor is provided at the bottom of the furnace body and a rotary crucible base driven by the rotary motor is provided at the bottom of the cylindrical inner cavity of the furnace body, wherein a seed rod position adjustment device is provided on the outer side of the furnace body, and wherein the seed rod position adjustment device is suspended with a seed rod movably inserted into the cylindrical inner cavity of the furnace body, and the crucible base and the seed rod rotate in opposite directions.

The specific description is as follows in conjunction with the accompanying drawings.

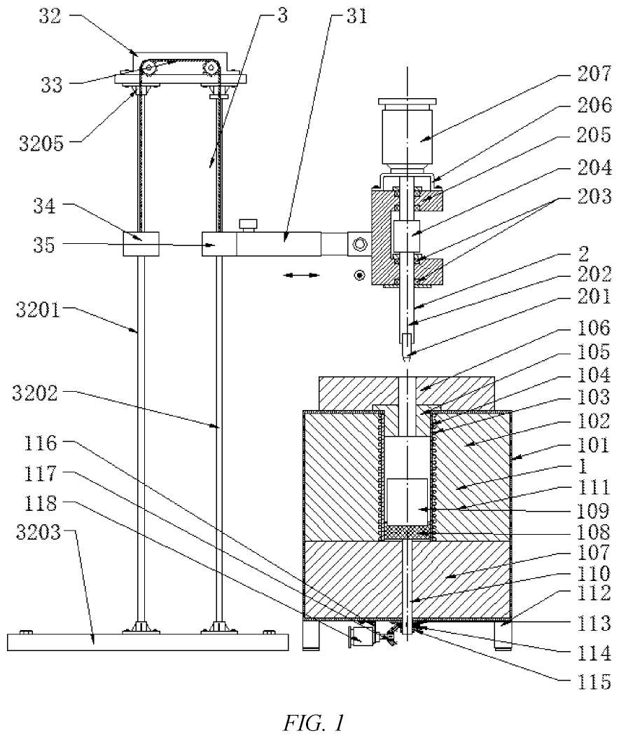

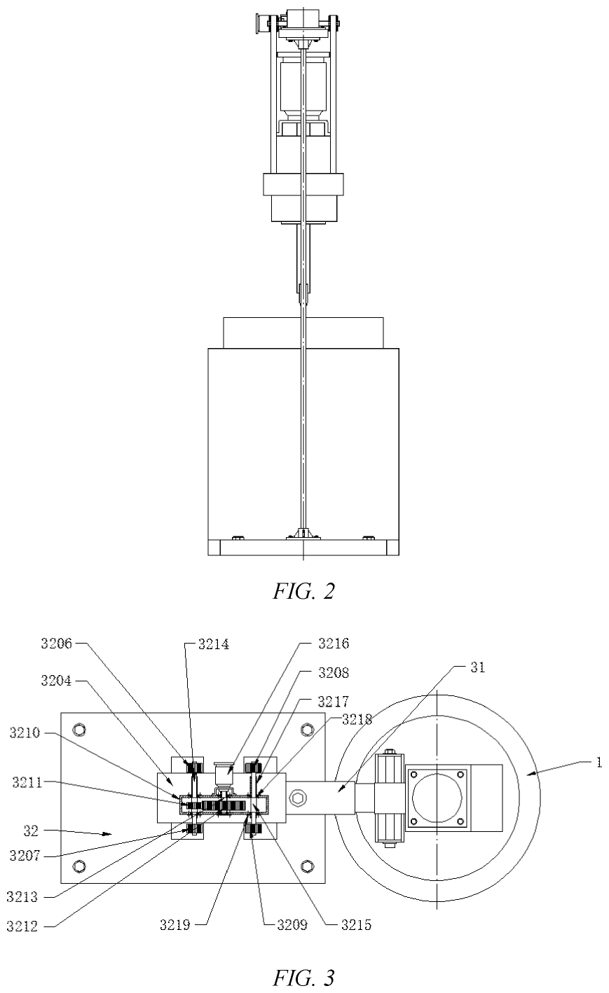

As shown in FIGS. 1 to 3, a molten salt furnace for preparing PZN-based large-size ternary high-performance single crystal comprises: a furnace body 1; a seed rod module 2 that penetrates into the furnace body as a crystal growth carrier and a seed rod position adjustment device 3, wherein the furnace body 1 is located below the seed rod module 2, the seed rod module 2 is fixed on the seed rod position adjustment device 3, and the seed rod 202 is centered by the seed rod position adjustment device 3, wherein the furnace body 1 includes a casing 101, a thermal insulation jacket 102 provided in the casing 101, a high-temperature furnace wire 103, a wire winding tube 104, a thermal insulation bottom plate 107, and a furnace body balance adjustment device 112 provided at the bottom of the casing 101.

As shown in FIGS. 1 to 3, the thermal insulation jacket 102 is located at the inner upper part of the casing 101 and the thermal insulation bottom plate 107 is located at the inner lower part of the casing 101. The thermal insulation jacket 102 is an annular cylindrical structure with its outer wall closely fitted to the inner wall of the casing 101. A heating device composed of the high-temperature furnace wire 103 and the wire winding tube 104 is located inside the annular cylindrical structure of the thermal insulation jacket 102. The upper and lower ends of the high-temperature furnace wire 103 and the wire winding tube 104 are flush with the upper and lower ends of the thermal insulation jacket 102, the high-temperature furnace wire 103 is wound on the outer wall of the wire winding tube 104, and the inner wall of the wire winding tube 104 is further provided with a thermocouple 111 connected to the high-temperature furnace wire 103.

As shown in FIGS. 1 to 3, a thermal insulation cover 106 and a heat preservation cover 105 are further arranged above the furnace body 1, wherein the thermal insulation cover 106 is located above the heat preservation cover 105, the lower end of the heat preservation cover 105 is closely fitted to the inner wall of the wire winding tube 104 and the upper end of the heat preservation cover 105 is connected the threaded groove provided at the bottom of the thermal insulation cover 106.

As shown in FIGS. 1 to 3, the bottom of the wire winding tube 104 is provided with a crucible base 108 supported by a support rod and a crucible 109 provided on the crucible base 108, wherein the other end of the support rod 110 extends out of the furnace body 1 and is sealed by a sealing block 113, the end of which is keyed to a first bevel gear 114 and locked by a locking block 115, and wherein the first bevel gear 114 meshes with the second bevel gear 117 connected to the output shaft of a rotary motor 118, and the rotary motor 118 is fixed on the bottom of the casing 101 through a motor support 116.

As shown in FIGS. 1 to 3, a seed rod module 2 is provided with a seed collet 201 in addition to the seed rod, wherein the seed collet 201 is fixed at one end of a seed rod 202, and the other end of the seed rod 202 is connected to an output shaft of a servo motor 207 through a coupling 204, wherein the servo motor 207 is fixed on a connecting seat 205 through a motor fixing bracket 206, and a guide bearing 203 is provided at the connection between the output shaft of the seed rod 202 and the servo motor 207 and the connecting seat 205.

As shown in FIGS. 1 to 3, the seed rod position adjustment device 3 includes an adjustment arm 31, a lifting adjustment seat 32, a lifting rack 33, a counterweight slider 34 and a lifting slider 35, wherein one end of the adjustment arm 31 is connected to the lifting slider 35 and other end to the seed rod module 2, wherein the lifting slider 35 is connected to the counterweight slider 34 through the lifting rack 33, and wherein the lifting rack 33 is connected to a first driving gear 3206, a second driving gear 3207, a first driven gear 3208 and a second driven gear 3209.

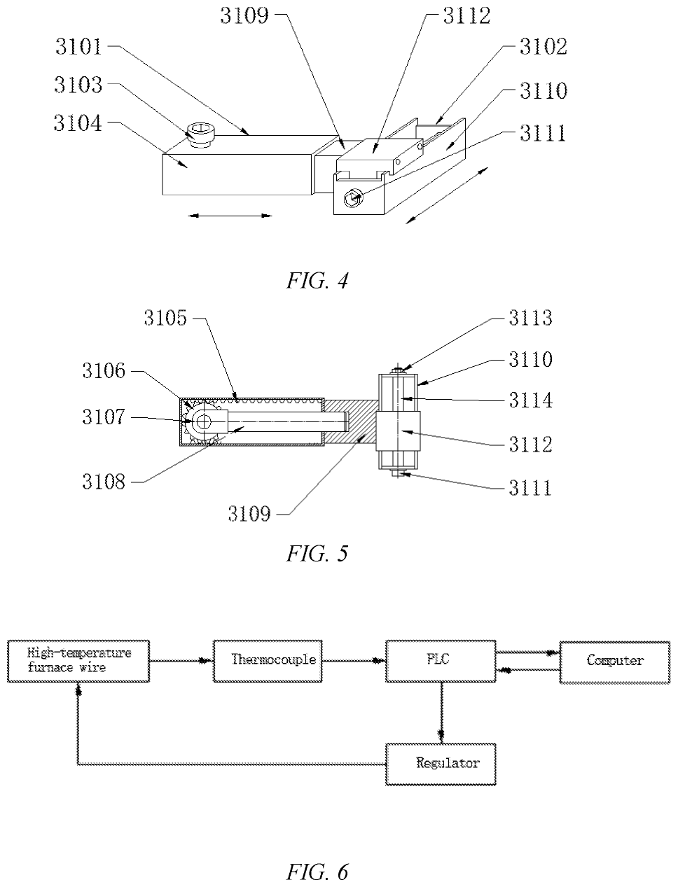

As shown in FIGS. 4 to 5, the adjustment arm 31 includes a left and right adjustment joint 3101 and a front and rear adjustment joint 3102, wherein one end of the left and right adjustment joint 3101 is connected to the lifting slider 35, and the other end is connected to the front and rear adjustment joint 3102, and wherein the other end of the front and rear adjustment joint 3102 is connected to a connecting seat 205 in the seed rod module 2.

As shown in FIG. 3, the left and right adjustment joint 3101 includes a left and right adjustment seat 3104 and a left and right rack 3105 arranged on the front and rear sides of the inner wall of the left and right adjustment seat 3104, wherein the left and right adjustment seat 3104 further includes a left and right adjustment gear 3106 meshing with the left and right rack 3105, wherein the left and right adjustment gear 3106 is connected to a left and right adjustment bolt 3103 which is rotated to drive the left and right adjustment gear 3106 to rotate; wherein the left and right adjustment gear 3106 is connected to one end of a left and right adjustment shaft 3108 through a connecting head 3107, and the other end of the left and right adjustment shaft 3108 is connected to a connecting body 3109 that is connected to the front and rear adjustment seat 3110 of the front and rear adjustment joint 3102; wherein the front and rear adjustment joint 3102 further includes a front and rear adjustment screw rod 3114, a front and rear adjustment slider 3112, a front and rear adjustment bolt 3111 and a front and rear adjustment screw rod lock nut 3113, wherein the front and rear adjusting screw rod 3114 is connected to the front and rear adjusting seat 3110 through the front and rear adjusting bolt 3111 and the front and rear adjusting screw rod lock nut 3113, and wherein the front and rear adjustment slider 3112 is threaded to the front and rear adjusting screw rod 3114.

As shown in FIG. 1, the lift adjustment seat 32 includes a first lifting rod 3201, a second lifting rod 3202, a base 3203 and a lifting fixing plate 3204, wherein the two ends of the first lifting rod 3201 and the second lifting rod 3202 are respectively fixed on the base 3203 and the lifting fixing plate 3204 through a lifting rod fixing seat 3205, and wherein the lifting fixing plate 3204 is further provided with a lifting driving component comprising a first driving gear 3206, a second driving gear 3207, a first driven gear 3208, a second driven gear 3209 and a gear box 3210, wherein the first driving gear 3206 and the second driving gear 3207 are connected to a gearbox 3210 through a driving shaft 3214, and the first driven gear 3208 and the second driven gear 3209 are connected to the gearbox 3210 through a driven shaft 3215, wherein a bearing 3218 is provided at the connection between the driving shaft 3214 and the driven shaft 3215 and the gearbox 3210, the bearing 3218 is fixed on the gearbox 3210 by a long bushing 3217 and a short bushing 3219, the long bushing 3217 is respectively arranged on one side of the first driving gear 3206 and the first driven gear 3208, and the short bushing 3219 is respectively arranged on one side of the second driving gear 3207 and the second driven gear 3209; wherein the gearbox 3210 is further provided with a first driving gear 3211 keyed to the driving shaft 3214 and a second driving gear 3212 keyed to a transmission shaft 3213, one end of the transmission shaft 3213 is connected to the gearbox 3210 and the other end is connected to the output shaft of the lifting drive motor 3216.

In the present invention, the casing 101 is made of stainless steel, and the crucible base 108 is made of corundum mullite. The furnace body 1 and the base 3203 are fixed on the ground after adjusting their balance. The thermal insulation cover 105 is provided with a viewing window and a lighting window.

As shown in FIG. 6, the internal temperature field of furnace body 1 is controlled by a PLC control system, and the high temperature is formed by starting the heating system to make the high temperature furnace wire 103 to heat the inside of furnace body 1. In the temperature control of molten salt furnace by PLC, the temperature is controlled and changed by adjusting the thyristor regulator to change the output current of the regulator.

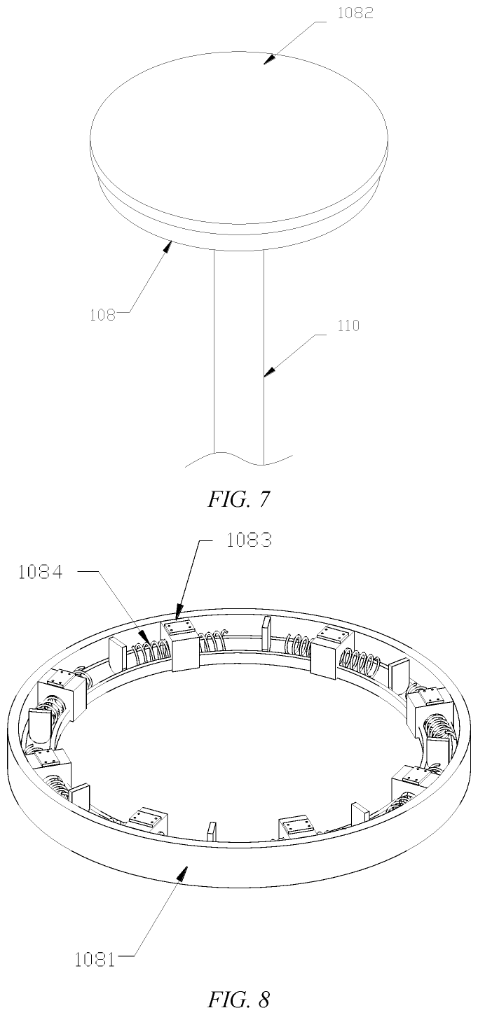

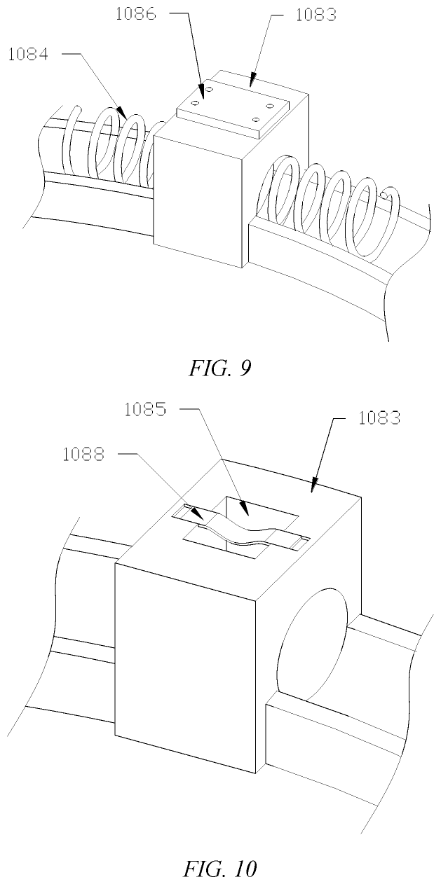

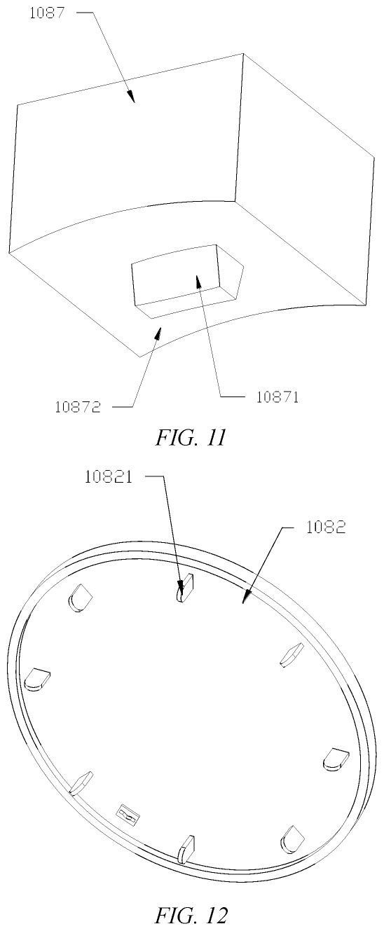

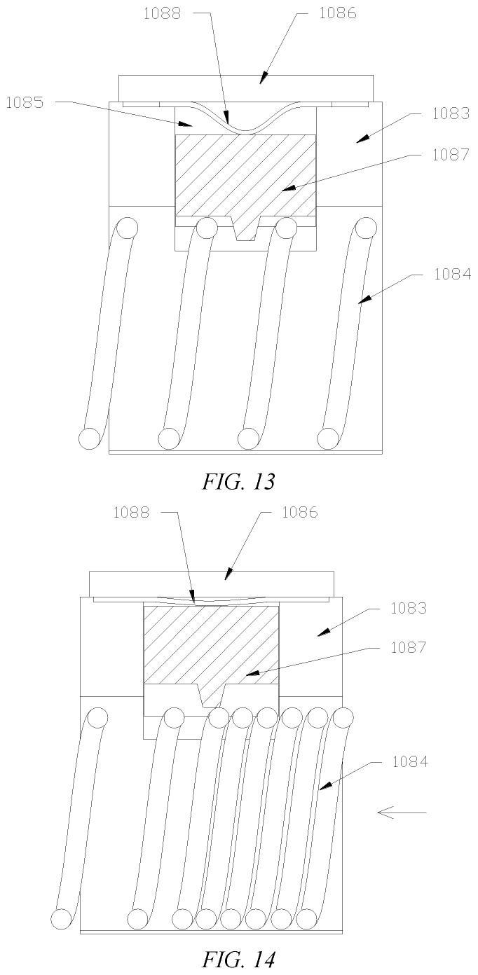

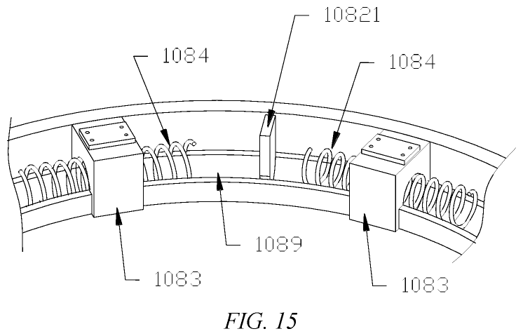

To alleviate the situation that the materials inside the crucible 109 are unstable due to inertia in the start stage when the crucible base 108 drives the crucible 109 to rotate, and the end stage when the crucible base 108 stops rotating by the rotary motor, as a preferred embodiment of the above-mentioned embodiments, as shown in FIGS. 7 to 15, the crucible base 108 includes a mounting base 1081 fixedly connected to the support rod, and a cover 1082 fitted with the top of the mounting base 1081 and supporting the crucible, wherein at least three guide blocks 1083 and buffer springs 1084 equal to the number of the guide blocks are evenly distributed inside the mounting seat 1081 along the circumferential direction, the buffer springs 1084 passing through horizontal through holes formed in the guide blocks 1083, the guide blocks 1083 are further provided with an installation groove 1085 in which a limit block 107 and an elastic pressing strip 1088 are arranged and a pressing plate 1086, the installation groove 1085 is configured to guide the limit block 1087 in a vertical direction, wherein the elastic pressing strip 1088 is fitted with the upper surface of the guide blocks 1083, which upper surface is provided with a guide groove for the two ends of the elastic pressing strip 1088 to slide, wherein the pressing plate 1086 is fitted with the top of the guide blocks 1083 to seal the top of the guide groove, and the elastic pressing strip 1088 provides a vertical downward pressing force for the limit block 1087 through elastic deformation; wherein a protrusion 10871 and two abutting surfaces 10872 located on either side of the protrusion 10871 in the length direction of the buffer springs 1084 are provided on the bottom of the limit block 1087, wherein the abutting surfaces 10872 are fitted with the buffer springs 1084, the protrusion 10871 is inserted between two adjacent turns of the buffer springs 1084 when the buffer springs 1084 are stationary, and the cross section of the protrusion 10871 in the radial direction of the buffer springs 1084 is an isosceles trapezoid; and wherein an inner side of the cover 1082 is provided with baffle plates 10821 equal to the number of the buffer springs 1084, wherein the baffle plates 10821 are arranged between two adjacent buffer springs 1084 to press the buffer springs 1084 on one side during the relative rotation of the mounting base 1081 and the cover 1082.

When the rotary motor 118 is started, the support rod 110 drives the mounting base 1081 to rotate, while the cover 1082 remains stationary due to inertia, and the buffer springs 1084 rotate synchronously with the guide blocks 1083 and the mounting seat 1081 under the effect of the limit block 1087. During the rotation, one side of the buffer springs 1084 first collides with the baffle plates 10821 provided on the cover 1082, so that the baffle plates 10821 are pushed relatively softly by the elasticity of the springs. During this pushing process, the portion of the buffer springs 1084 on the side of the protrusion 10871 of the limit block 1087 is pressed. The process described above is the first-stage buffering startup process. When one side of the buffer springs 1084 is compressed to a certain degree, the outer diameter will increase to an appropriate extent relative to that before being compressed. With the above increase, the buffer springs 1084 compress the limit block 1087 upward through the abutting surfaces 10872, so that the limit block 1087 obtains the trend of upward movement. Under this trend, and with the guidance of the inclined surface of the side wall of the protrusion 10871, the protrusion 10871 moves upward under the compression of the buffer springs 1084, thereby releasing the blocking effect on the buffer springs 1084. Of course, in the above process, since the limit block 1087 is pressed by the elastic pressing strip 1088, the movement process is also soft, so that the buffer springs 1084 press the baffle plates 10821 relatively softly. This process is the second-stage buffering startup process. The buffering process is over until the baffle plates 10821 come into contact with the guide blocks 1083, and normal power transmission is realized. The limit block 1087 will reinsert the protrusion 10871 between the two turns of the buffer springs after the buffer springs 1084 are stabilized. The substances in the crucible 109 obtain a more stable state due to the two-stage buffering, which ensures the growth environment of the crystal.

When the rotary motor 118 stops, the support rod 110 controls the mounting seat 1081 to stop rotating, while the cover 1082 continues to rotate due to inertia, so that the baffle plates 10821 move from the position where they are fitted with the limit block 1087 to the position where they press the buffer springs 1084 on the other side. After the baffle plates 10821 come into contact with the buffer springs 1084 on the other side, the movement is made relatively soft due to the buffering effect of the buffer springs 1084. During this process, the portion of the buffer springs 1084 on the other side of the protrusion 10871 is pressed, and the above process is the first-stage buffering stop process. When the other side of the buffer springs 1084 is compressed to a certain degree, likewise, the outer diameter will increase to an appropriate extent relative to that before being compressed. With the above increase. With such increase, the buffer springs 1084 will press the limit block 1087 upward through the abutting surfaces 10872, so that the limit block 1087 obtains the trend of upward movement again. Under this trend, and with the guidance of the inclined surface of the side wall of the protrusion 10871, the protrusion 10871 moves upward under the compression of the buffer springs 1084, thereby releasing the blocking effect on the buffer springs 1084. Likewise, in the above process, since the limit block 1087 is pressed by the elastic pressing strip 1088, the movement process is also soft, so that the buffer springs 1084 press the baffle plates 10821 relatively softly. This process is the second-stage buffering stop process. The buffering process is over until the baffle plates 10821 fit with the guide blocks 1083 on the other side, and the cover 1082 drives the crucible to stop rotating. The limit block 1087 will reinsert the protrusion 10871 between the two turns of the buffer springs after the buffer springs 1084 are stabilized.

During the above start and stop process, the buffer springs realize buffering at different stages through the reciprocating action in the through holes of the guide blocks 1083. On the one hand, the limit block 1087 realizes the limit effect on the springs, on the other hand, it also promotes the secondary buffering. The multi-stage buffering effectively improves the stability of the environment in the crucible, ensuring the stability of the crystal production environment. Except for the buffer springs 1084 and the elastic pressing strip 1088, the above structure can be made of corundum mullite, with low structural complexity and easy processing.

The mounting seat 1081 and the cover 1082 can be directly fitted, and horizontal positioning can be achieved by the peripheral fit, and there is no need for fixing in the height direction. In order to reduce difficulty in installing the pressing plate 1086, the pressing plate 1086 can also be pressed vertically and downward through the cover. In this case, it is only necessary to provide a protruding portion on the pressing plate 1086 which inserts into a concave portion in the guide blocks 1083 to realize the limit in the horizontal direction.

To ensure that the position of the buffer springs 1084 are more in line with the movement track of the baffle plate 10821, an annular groove 1089 may be provided in the mounting seat 1081. Installing the buffer springs 1084 in the annular groove 1089 can make the buffer springs 1084 obtain an appropriate radian and better fit with the baffle 10821.

The working principle of the molten salt furnace for preparing PZN-based large-size ternary high-performance single crystal is described below. First, clean the crucible 109 and put it on the crucible base 108, load the composite flux and raw materials into the crucible 109, install the seed on the seed collet 201, adjust the adjustment arm 31 of the seed rod position adjustment device 3 to center the seed rod; then start the temperature control system to heat up and melt the raw materials, and after the raw materials are all melted, adjust the temperature to a suitable temperature by controlling the temperature control system, and then start the lifting adjustment seat 32 for seeding; after the seed contacts the liquid surface, adjust the temperature according to the weight and the diameter of the seed contacting the liquid surface, until the seed basically does not change within a period of time, indicating that the seeding is successful; set the crystal growth process parameters, run the automatic growth program for automatic growth; after the automatic growth is complete, run the cooling program to control the temperature control system to cool the crystal; and take out the crystal when the temperature in the furnace drops to room temperature.

1) The molten salt furnace of the present invention meets the reality of using composite flux, effectively reducing the growth temperature and the volatilization of raw materials, so that the raw materials can be grown at a lower temperature. This reduces the volatilization of raw materials while reducing the corrosion of platinum crucibles, realizing stable growth of crystals, and ensuring the uniformity of the quality of each grown crystal.

2) The molten salt furnace according to the present invention controls the heating gradient through the temperature control system to realize accurate control of the temperature in the furnace. The top seed rod rotates under the drive of the servo motor, and the crucible rotates reversely under the action of the bottom rotary motor to achieve melt convection, so as to make the change of crystal diameter adapt to the thermal inertia of the thermal insulation system in the furnace, effectively reducing the crystal inclusions and improving the yield of the crystal.

The above descriptions are only preferred embodiments of the present invention, and are not intended to limit the present invention in any form. Although the present invention has been illustrated above with preferred embodiments, it is not intended to be limited thereto. Any person skilled in the art can make some changes or modifications to equivalent embodiments by using the above disclosed technical contents without departing from the scope of the technical solution of the present invention. Any simple modifications, equivalent changes and modifications made to the above embodiments according to the technical essence of the present invention still fall within the scope of the technical solutions of the present invention.

1. A PZN-based large-size ternary high-performance single crystal represented by formula (1-x-y)Pb(B′_{1/2}B″_{1/2})O₃-yPb(Zn_{1/3}Nb_{2/3})O₃-xPbTiO₃, wherein B′ is Mg, Fe, Sc, Ni, In, Yb, Lu and/or Ho, B″ is Nb, Ta and/or W, 0.4<x<0.6, 0.1<y<0.4, 0.1<1-x-y<0.4.

2. A method for preparing the PZN-based large-size ternary high-performance single crystal according to claim 1, comprising the steps of:
mixing of raw materials (S1), including weighing raw materials according to the stoichiometric ratio of the single crystal, adding a flux to the raw materials, mixing the raw materials and the flux evenly and grinding the same, and loading the resultant into a crucible for subsequent use,
positioning of seed (S2), including transferring the crucible containing the raw materials and flux to a molten salt furnace, fixing a seed on a seed rod, adjusting the position of the seed rod in the molten salt furnace so that the molten salt furnace, crucible and seed are centered on a line;
crystal growth (S3), including heating the materials in the crucible to a molten state and maintaining the same at a constant temperature to obtain a melt, then moving the seed rod to adjust the seed to meet the liquid level of the melt, followed by cooling to a temperature below the saturation point for crystal growth, wherein during the growth process, the convective changes of the melt are adjusted by rotating the seed rod and crucible;
cooling and annealing (S4), including lifting the crystal from the melt when the crystal grows to a preset size, and cooling and annealing the crystal to obtain the final PZN-based large-size ternary high-performance single crystal.

3. The method for preparing the PZN-based large-size ternary high-performance single crystal according to claim 2, wherein the seed in the step S2 has the same composition as the PZN-based large-size ternary high-performance single crystal prepared by cooling and annealing in the step S4, and wherein the growth orientation of the seed is [111] or [001].

4. The method for preparing the PZN-based large-size ternary high-performance single crystal according to claim 2, wherein the flux is one of two mixtures of PbO and B₂O₃ or PbO and PbF₂.

5. A molten salt furnace for use in the method for preparing the PZN-based large-size ternary high-performance single crystal according to claim 2, comprising a furnace body provided with a cylindrical inner cavity, wherein a rotary motor is provided at the bottom of the furnace body and a rotary crucible base driven by the rotary motor is provided at the bottom of the cylindrical inner cavity of the furnace body, wherein a seed rod position adjustment device is provided on the outer side of the furnace body, and wherein the bottom of the seed rod position adjustment device fixes a seed rod inserted into the cylindrical inner cavity of the furnace body and drives the seed rod to rotate the crucible base.

6. The molten salt furnace according to claim 5, wherein the crucible base is supported at the bottom of the cylindrical inner cavity through a support rod, wherein a lower end of the support rod extends to the outside of the furnace body and is fixedly provided with a first bevel gear, and wherein an end of output shaft of the rotary motor is connected to a second bevel gear meshed with the first bevel gear.

7. The molten salt furnace according to claim 6, wherein the crucible base includes a mounting seat fixedly connected to the support rod, and a cover fitted with the top of the mounting seat and supporting the crucible;
wherein at least three guide blocks and buffer springs equal to the number of the guide blocks are evenly distributed inside the mounting seat along the circumferential direction, the buffer springs passing through horizontal through holes formed in the guide blocks, the guide blocks are further provided with an installation groove in which a limit block and an elastic pressing strip are arranged and a pressing plate, the installation groove is configured to guide the limit block in a vertical direction, wherein the elastic pressing strip is fitted with the upper surface of the guide blocks, which upper surface is provided with a guide groove for the two ends of the elastic pressing strip to slide, wherein the pressing plate is fitted with the top of the guide blocks to seal the top of the guide groove, and the elastic pressing strip provides a vertical downward pressing force for the limit block through elastic deformation;
wherein a protrusion and two abutting surfaces located on either side of the protrusion in the length direction of the buffer springs are provided on the bottom of the limit block, wherein the abutting surfaces are fitted with the buffer springs, the protrusion is inserted between two adjacent turns of the buffer springs when the buffer springs are stationary, and the cross section of the protrusion in the radial direction of the buffer springs is an isosceles trapezoid; and
wherein an inner side of the cover is provided with baffle plates equal to the number of the buffer springs, wherein the baffle plates are arranged between two adjacent buffer springs to press the buffer springs on one side during the relative rotation of the mounting base and the cover.

8. The molten salt furnace according to claim 6, wherein the seed rod position adjustment device includes a base on which a lifting fixing plate is vertically arranged, wherein a first lifting rod and a second lifting rod are provided in parallel on either side of the lifting fixing plate, a first driving gear opposite to the first lifting rod and a second driving gear opposite to the second lifting rod are provided on the top of the lifting fixing plate, wherein the first lifting rod is provided with a counterweight slider that slides up and down and the second lifting rod is provided with a lifting slider that slides up and down, the counterweight slider and the lifting slider being controlled by a lifting rack meshed with the first driving gear and the second driving gear of a lifting driving component, and wherein the lifting slider is connected to an adjustment arm, the bottom of the adjustment arm fixing the seed rod.

9. The molten salt furnace according to claim 8, wherein the adjustment arm comprises a left and right adjustment joint having one end connected to the lifting slider and the other end connected to one end of a front and rear adjustment joint, the bottom of the front and rear adjustment joint fixing the seed rod.

10. The molten salt furnace according to claim 9, wherein the other end of the front and rear adjustment joint is provided with a connecting seat connected to a motor fixing bracket on which a servo motor is arranged, an output shaft of the servo motor being connected to the seed rod through a coupling.
